(19) United States
(12) Patent Application Publication
(10) Pub. No.: US 2026/0214913 A1
(43) Pub. Date: Jul. 23, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventor: Young Kun JEE, Suwon-si (KR)

(73) Assignee: SAMSUNG ELECTRONICS CO., LTD., Suwon-si (KR)

(21) Appl. No.: 19/290,923

(22) Filed: Aug. 5, 2025

(30) Foreign Application Priority Data
Jan. 21, 2025 (KR) 10-2025-0008973
Feb. 25, 2025 (KR) 10-2025-0024061

(51) Int. Cl. H01L 23/00; H01L 23/31; H01L 23/367; H01L 23/538; H01L 25/18; H10B 80/00; H10D 80/30

(52) U.S. Cl. CPC H10B 80/00; H10D 80/30; H10W 90/00; H10W 40/22; H10W 70/611; H10W 72/325; H10W 72/352; H10W 72/354; H10W 74/121; H10W 74/15; H10W 90/20; H10W 90/297; H10W 90/401; H10W 90/724; H10W 90/732; H10W 90/734; H10W 90/792

(57) ABSTRACT

A semiconductor package a includes a first semiconductor chip, a plurality of second semiconductor chips stacked on the first semiconductor chip, and a third semiconductor chip on the second semiconductor chips, and an adhesive layer between the third semiconductor chip and an uppermost second semiconductor chip of the second semiconductor chips. The second semiconductor chips are connected to one another via direct contact of bonding pads. The adhesive layer comprises a polymer and a metal filler.

### CROSS-REFERENCE TO RELATED APPLICATIONS

This U.S. non-provisional patent application claims priority under 35 U.S.C. § 119 to Korean Patent Application Nos. 10-2025-0008973 and 10-2025-0024061, filed on Jan. 21, 2025 and Feb. 25, 2025, respectively, in the Korean Intellectual Property Office, the entire contents of which are hereby incorporated by reference.

### BACKGROUND

The embodiments of inventive concept relate to a semiconductor package and a manufacturing method thereof, and more particularly, to a semiconductor package comprising a plurality of stacked semiconductor chips and a manufacturing method thereof.

With the rapid development of the electronics industry, higher performance of electronic devices is required. Accordingly, there is an increasing need for a method of arranging a plurality of semiconductor chips to realize higher performance. Accordingly, a semiconductor package in which a plurality of semiconductor chips having through vias are stacked in a vertical direction has been proposed.

### SUMMARY

The embodiments of inventive concept may increase reliability of a semiconductor package.

A semiconductor package according to some embodiments may comprise a first semiconductor chip, a plurality of second semiconductor chips stacked on the first semiconductor chip, a third semiconductor chip on the second semiconductor chips, and an adhesive layer between the third semiconductor chip and an uppermost second semiconductor chip of the second semiconductor chips, wherein the second semiconductor chips may be connected to each other via direct contact of the bonding pads, and wherein the adhesive layer may comprise a polymer and a metal filler.

A semiconductor package according to some embodiments may comprise a first semiconductor chip, a plurality of second semiconductor chips stacked on the first semiconductor chip, a third semiconductor chip on the second semiconductor chips, and an adhesive layer between the third semiconductor chip and an uppermost second semiconductor chip of the second semiconductor chips, wherein each of the second semiconductor chips may comprise an upper insulating layer disposed at an upper end thereof and a lower insulating layer disposed at a lower end thereof, wherein an upper insulating layer of a lower second semiconductor chip of two vertically adjacent second semiconductor chips may be in direct contact with a lower insulating layer of the upper second semiconductor chip, wherein each of the upper insulating layer and the lower insulating layer may comprise a dielectric, and wherein the adhesive layer may comprise a polymer matrix and a metal filler in the polymer matrix.

A semiconductor package according to some embodiments may comprise a package substrate, an interposer substrate on the package substrate, a semiconductor chip on the interposer substrate, and a chip stack structure that may be separated from the semiconductor chip in a horizontal direction, wherein the chip stack structure may comprise a first semiconductor chip, a plurality of second semiconductor chips stacked on the first semiconductor chip, a third semiconductor chip on the second semiconductor chips, an adhesive layer between the third semiconductor chip and an uppermost second semiconductor chip of the second semiconductor chips, and a first mold layer disposed on the first semiconductor chip and covering side surfaces of the second semiconductor chips, a side surface of the third semiconductor chip, and a side surface of an adhesive layer, wherein each of the first semiconductor chip and the second semiconductor chips may comprise through vias, wherein the adhesive layer may comprise a polymer and a metal filler, and wherein a level of the upper surface of the adhesive layer may be lower than a level of the upper surface of the semiconductor chip.

A method for manufacturing a semiconductor package according to some embodiments may comprise preparing a first wafer, stacking first semiconductor chips on the first wafer one after another in a vertical direction, and adhering a second semiconductor chip on an uppermost first semiconductor chip of the first semiconductor chips, wherein the first semiconductor chips each may comprise an upper pad, a lower pad, and a through via connecting them, wherein the stacking the first semiconductor chips may comprise directly contacting an upper pad of a lower first semiconductor chip and a lower pad of an upper first semiconductor chip of adjacent first semiconductor chips in the vertical direction, wherein the adhering the second semiconductor chip may comprise disposing an adhesive film on one surface of the second semiconductor chip, disposing the adhesive film on an upper surface of the uppermost first semiconductor chip, and applying thermocompression bonding to the second semiconductor chip toward the first wafer, and wherein the adhesive film may comprise a thermosetting resin and a metal filler.

According to some embodiments, stacking the first semiconductor chips may further comprise subjecting an upper surface of a lower first semiconductor chip and a lower surface of an upper first semiconductor chip of the vertically adjacent first semiconductor chips to plasma treatment.

According to some embodiments, the method of manufacturing a semiconductor package may further comprise forming the second semiconductor chip, wherein forming the second semiconductor chips may comprise preparing a second wafer comprising a semiconductor substrate, disposing an adhesive film on the second wafer, and sawing the adhesive film and the second wafer.

According to some embodiments, preparing the second wafer may comprise forming an insulating layer on the semiconductor substrate, and forming a metal pattern on the insulating layer.

According to some embodiments, a thickness of the metal pattern may be greater than a thickness of the upper pad and a thickness of the lower pad.

According to some embodiments, the second semiconductor chip may have a first width in a horizontal direction, the first semiconductor chip may have a second width in the horizontal direction, and the first width and the second width may be the same.

According to some embodiments, the thermosetting resin may comprise at least one of an epoxy resin, an acrylic resin, a polyimide resin, and a polyurethane resin.

According to some embodiments, the metal filler may comprise at least one metal of gold (Au), copper (Cu), nickel (Ni), aluminum (Al), and silver (Ag) or an oxide thereof.

According to some embodiments, the adhesive film may comprise the metal filler in a volume ratio of 60 vol % to 90 vol %.

According to some embodiments, the method may further comprise forming a mold layer covering an upper surface of the first wafer, side surfaces of the first semiconductor chips, and a side surface of the second semiconductor chip, and sawing the mold layer and the first wafer.

A method for manufacturing a semiconductor package according to some embodiments may comprise preparing a wafer, vertically stacking first semiconductor chips one after another on the wafer, attaching an adhesive film on one surface of a second semiconductor chip, and thermocompression-bonding the adhesive film with an upper surface of an uppermost first semiconductor chip of the first semiconductor chips to form an adhesive layer, wherein the adhesive layer may comprise a polymer and a metal filler, and the vertically stacking the first semiconductor chips one after another on the wafer may comprise directly contacting an upper insulating layer of a first semiconductor chip located below and a lower insulating layer of the first semiconductor chip located above of two first semiconductor chips vertically adjacent to each other, and wherein the upper insulating layer and the lower insulating layer each may comprise a dielectric.

According to some embodiments, the lower insulating layer and the upper insulating layer each may comprise any one of silicon oxide, silicon nitride, and silicon oxynitride.

According to some embodiments, a thickness of the second semiconductor chip may be greater than a thickness of each of the first semiconductor chips.

According to some embodiments, the second semiconductor chip may have a first width in a horizontal direction, each of the first semiconductor chips has a second width in the horizontal direction, and the first width and the second width may be the same.

A method of manufacturing a semiconductor package according to some embodiments may comprise forming a chip stack structure, mounting a first semiconductor chip and the chip stack structure spaced apart in a horizontal direction on an interposer substrate, and mounting the interposer substrate on the package substrate, wherein forming the chip stack structure may comprise preparing a wafer, stacking second semiconductor chips on the wafer one after another in a vertical direction, adhering a third semiconductor chip on an uppermost second semiconductor chip of the second semiconductor chips, and sawing the wafer to form a fourth semiconductor chip, wherein stacking the second semiconductor chips may comprise directly contacting bonding pads of adjacent second semiconductor chips in the vertical direction, and the adhering the third semiconductor chip may comprise disposing an adhesive film on one surface of the third semiconductor chip, and disposing the adhesive film on an upper surface of the uppermost second semiconductor chip, wherein the adhesive film may comprise a thermosetting resin and a metal filler.

According to some embodiments, the method of manufacturing a semiconductor package may further comprise forming a mold layer on the interposer substrate, the mold layer filling between the first semiconductor chip and the chip stack structure and covering a side surface of the first semiconductor chip and a side surface of the chip stack structure.

According to some embodiments, the method of manufacturing a semiconductor package may further comprise forming a thermally conductive material layer on the mold layer and an upper surface of the first semiconductor chip, an upper surface of a chip stack structure, and disposing a heat sink on the thermally conductive material layers.

According to some embodiments, the third semiconductor chip may comprise a metal pattern on a lower surface thereof, the metal pattern being vertically spaced apart from an uppermost one of the second semiconductor chips.

According to some embodiments, the metal filler may comprise at least one metal of gold (Au), copper (Cu), nickel (Ni), aluminum (Al), and silver (Ag) or an oxide thereof, and the adhesive film may comprise the metal filler in a volume ratio of 60 vol % to 90 vol %.

According to some embodiments, the third semiconductor chip may be a dummy chip.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to some embodiments.

FIG. 2 is a cross-sectional view taken along line A-A′ in FIG. 1.

FIG. 3 is an enlarged view of ‘EX1’ of FIG. 2.

FIG. 4 is a diagram conceptually representing an upper surface and a lower surface of each of the semiconductor chips of FIG. 2.

FIG. 5 is a cross-sectional view of a semiconductor package in according to some embodiments.

FIG. 6 is an enlarged view of ‘EX2’ of FIG. 5.

FIG. 7 is an enlarged view corresponding to ‘EX2’ in FIG. 5.

FIGS. 8, 9, 10, 11, and 12 are cross-sectional views illustrating a method of manufacturing a semiconductor package according to some embodiments.

FIG. 13 is a plan view of a semiconductor package according to some embodiments.

FIG. 14 is a cross-sectional view taken along line B-B′ in FIG. 13.

FIG. 15 is a cross-sectional view taken along line B-B′ in FIG. 13.

### DETAILED DESCRIPTION

Example embodiments of the inventive concepts will now be described more fully with reference to the accompanying drawings, in which example embodiments are shown.

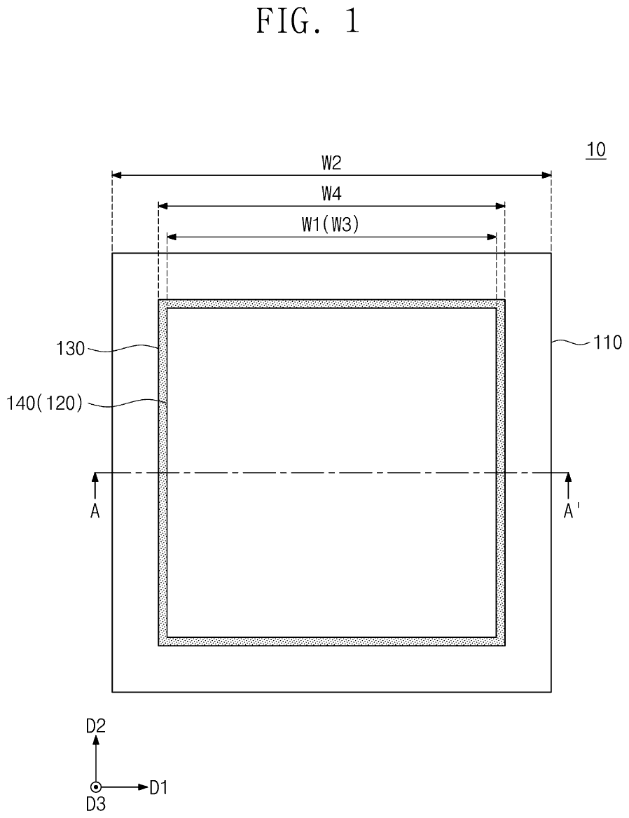

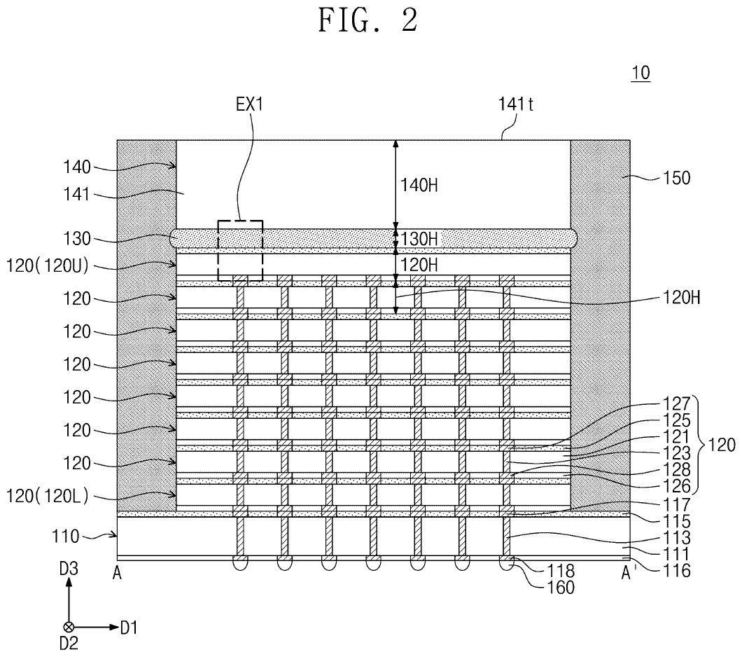

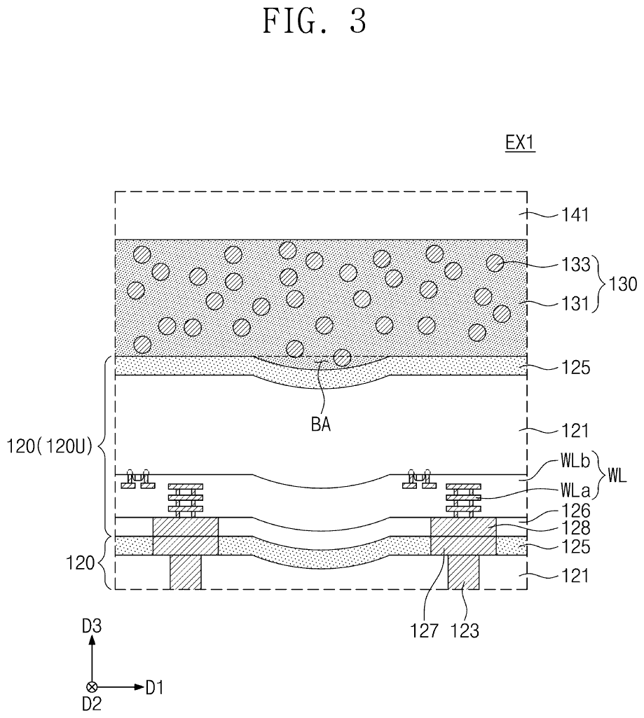

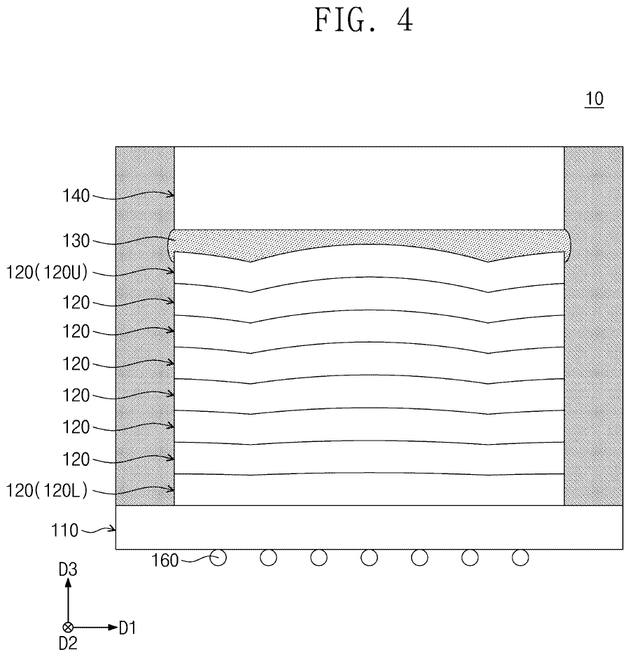

FIG. 1 is a plan view of a semiconductor package according to some embodiments. FIG. 2 is a cross-sectional view taken along line A-A′ in FIG. 1. FIG. 3 is an enlarged view of ‘EX1’ of FIG. 2. FIG. 4 is a diagram conceptually representing of the upper and lower surfaces of each of the semiconductor chips of FIG. 2.

Referring to FIGS. 1, 2, and 3, the semiconductor package 10 according to some embodiments may be, for example, a high bandwidth memory (HBM). The semiconductor package 10 may also be referred to herein as a chip stack structure 10. The semiconductor package 10 may comprise a first semiconductor chip 110, second semiconductor chips 120, a third semiconductor chip 140, and a mold layer 150.

In this specification, one direction parallel to the upper surface of the first semiconductor chip 110 is defined as a first direction D1. Other direction parallel to the upper surface of the first semiconductor chip 110 and perpendicular to the first direction D1 is defined as a second direction D2. Another direction perpendicular to the upper surface of the first semiconductor chip 110 is defined as a third direction D3. A horizontal direction herein may correspond to the first direction D1 or the second direction D2, and a vertical direction may correspond to the third direction D3.

Referring to FIGS. 1 and 2, the first semiconductor chip 110 may be disposed at a lower portion of the semiconductor package 10. The first semiconductor chip 110 may also be referred to herein by the name logic die, logic chip, base die, buffer chip, buffer die, memory controller, or the like. The first semiconductor chip 110 may be a serial-parallel conversion circuit, a design for test (DFT), a Joint Test Action Group (JTAG), a test logic circuit such as memory built-in self-test (MBIST), or a signal interface circuit such as PHY. In exemplary embodiments, a horizontal area of first semiconductor chip 110 may be greater than a horizontal area of second semiconductor chip 120, and a horizontal area of third semiconductor chip 140.

The first semiconductor chip 110 may comprise a first semiconductor substrate 111, a first through via 113, a first upper insulating layer 115, a first upper bonding pad 117, a first lower insulating layer 116, an under-bump pattern 118, and a connection terminal 160.

The first semiconductor substrate 111 may comprise a semiconductor material such as silicon, and germanium. The first semiconductor substrate 111 may comprise a lower surface and an upper surface facing each other. For example, the lower surface may be an active surface and the upper surface may be an inactive surface. A plurality of individual devices may be disposed in the active surface, wherein the plurality of individual devices may comprise, for example, transistors. The first lower insulating layer 116 and the under-bump pattern 118 may be disposed on the lower surface of the first semiconductor substrate 111.

The first semiconductor chip 110 may further comprise a first wiring layer disposed on the active surface. The first wiring layer may be disposed between the first semiconductor substrate 111 and the first lower insulating layer 116. The first wiring layer may be, for example, a front-end-of-line (FEOL) layer or a back-end-of line (BEOL) layer. The first wiring layer may comprise a first insulating layer and a first wiring structure in the first insulating layer. The first wiring structure may comprise a plurality of wiring lines and vias connected therewith. The first wiring layer may electrically connect the under-bump pattern 118 and the first through via 113, and electrically connect the individual devices and the under-bump pattern 118.

The first through via 113 may pass through the first semiconductor substrate 111. The first through via 113 may comprise a conductive material, such as copper, for example. An anti-diffusion pattern such as tantalum nitride (TaN), tantalum (Ta), titanium nitride (TiN), and tungsten (W) may be disposed between the first through via 113 and the first semiconductor substrate 111. One end of the first through via 113 may be connected with the first upper bonding pad 117, and the other end may be connected with the first wiring structure. The first through via 113 may overlap the first upper bonding pad 117 and the under-bump pattern 118 in the vertical direction D3.

The first upper insulating layer 115 may be disposed on the upper surface of the first semiconductor substrate 111. The first upper insulating layer 115 may cover the upper surface of the first semiconductor substrate 111. The first upper insulating layer 115 may comprise, for example, silicon oxide, silicon nitride, or silicon oxynitride. The first upper bonding pad 117 may penetrate the first upper insulating layer 115 in the vertical direction D3. A side surface of the first upper bonding pad 117 may be covered by the first upper insulating layer 115. The under-bump pattern 118 may be disposed on the lower surface of the first semiconductor substrate 111. Side surface of the under-bump pattern 118 may be covered by the first lower insulating layer 116, or may protrude and be exposed from the first lower insulating layer 116. The first upper bonding pad 117 and the under-bump pattern 118 may overlap with each other in the vertical direction D3. For example, the first upper bonding pad 117 and the under-bump pattern 118 may each comprise copper (Cu).

A plurality of second semiconductor chips 120 may be stacked on the first semiconductor chip 110. The second semiconductor chips 120 may be stacked in the vertical direction D3 on the upper surface of the first semiconductor chip 110. Each of the second semiconductor chips 120, 120L, 120U may be a memory chip. The second semiconductor chip 120 may be, for example, any one of DRAM, SRAM, and NAND-FLASH. The second semiconductor chips 120, 120L, 120U may be the same type of semiconductor chip having the same integrated circuit. The second semiconductor chip 120 may also be referred to as a core die or a core chip.

Although eight second semiconductor chips 120 are illustrated as being stacked in FIG. 1, in accordance with other embodiments, multiples of four, e.g., twelve or sixteen, second semiconductor chips 120 may be stacked.

In the following, for the convenience of description, the second semiconductor chip 120 located at the lowermost end among the plurality of second semiconductor chips 120 may be referred to as a lowermost second semiconductor chip 120L, and the second semiconductor chip 102 located at the uppermost end among the second semiconductor chips 120 is referred to as an uppermost second semiconductor chip 120U.

The plurality of second semiconductor chips 120 except for the uppermost second semiconductor chip 120U may each comprise a second semiconductor substrate 121, a plurality of second through vias 123, a second upper insulating layer 125, a second lower insulating layer 126, a plurality of second upper bonding pads 127, and a plurality of second lower bonding pads 128. The uppermost second semiconductor chip 120U may comprise a second semiconductor substrate 121, a second upper insulating layer 125, a second lower insulating layer 126, and a plurality of second lower bonding pads 128. That is, unlike the other second semiconductor chips 120, the uppermost second semiconductor chip 120U may not comprise the second through via 123 and the second upper bonding pad 127.

The second semiconductor substrate 121 may be formed of substantially the same or similar material as the first semiconductor substrate 111. For example, the second semiconductor substrate 121 may comprise silicon (Si). The second semiconductor chip 120 may have a structure similar to that of the first semiconductor chip 110. For example, the second semiconductor substrate 121 has an active surface and an inactive surface opposite to the active surface. Various kinds of individual devices may be formed in the active surface. In addition, the second semiconductor chip 120 may further comprise a second wiring layer WL disposed on the active surface. The second wiring layer WL may be, for example, a FEOL layer or a BEOL layer. The second wiring layer WL may comprise a second insulating layer WLb and a second wiring structure WLa in the second insulating layer WLb. The second wiring structure WLa may comprise a plurality of wiring lines and vias connected therewith. The second wiring layer WL electrically connects the second lower bonding pad 128 and the second through via 123, and electrically connects the individual devices and the second lower bonding pad 128.

The second through via 123 may penetrate the second semiconductor substrate 121. The second through via 123 may comprise a conductive material, such as copper, for example. A diffusion prevention pattern (ex: tantalum nitride (TaN)) may be disposed between the second through via 123 and the second semiconductor substrate 121. One end of the second through via 123 may be connected with the second upper bonding pad 127, and the other end may be connected with the second wiring structure WLa.

The second upper insulating layer 125 may be disposed on an upper surface of the second semiconductor substrate 121, and the second lower insulating layer 126 may be disposed on a lower surface of the second semiconductive substrate 121. The second upper insulating layer 125 may cover the upper surface of the second semiconductor substrate 121, and the second lower insulating layer 126 may cover the lower surface of the second semiconductive substrate 121. The second upper insulating layer 125 and the second lower insulating layer 126 may be formed of substantially the same or similar materials as the first upper insulating layer 115 and the first lower insulating layer 116, respectively.

The plurality of second upper bonding pads 127 may be disposed on an upper surface of the second semiconductor substrate 121. The second upper bonding pad 127 may penetrate the second upper insulating layer 125 in the vertical direction D3. Side surfaces of the second upper bonding pad 127 may be covered by the second upper insulating layer 125. The plurality of second lower bonding pads 128 may be disposed on the lower surface of the second semiconductor substrate 121. The second lower bonding pad 128 may penetrate the second lower insulating layer 126 in the vertical direction D3. Side surfaces of the second lower bonding pad 128 may be covered by the second lower insulating layer 126. The second upper bonding pad 127 and the second lower bonding pad 128 may overlap with each other in the vertical direction D3. The second upper bonding pad 127 and the second lower bonding pad 128 may each be formed of substantially the same or similar material as the first upper bonding pad 117 and the under-bump pattern 118, respectively.

The lowermost second semiconductor chip 120L may be connected to the first semiconductor chip 110 through direct contact of bonding pads. The second semiconductor chips 120 may be connected via direct contact of the bonding pads. Direct contact of the bonding pads means metal-metal direct bonding. Specifically, the second lower bonding pad 128 of the lowermost second semiconductor chip 120L and the first upper bonding pad 117 of the first semiconductor chip 110 may be in direct contact and connected to each other in the vertical direction D3. The second upper bonding pad 127 of one second semiconductor chip 120 may be in direct contact with and connected to the second lower bonding pad 128 of another second semiconductor chip 120 disposed on the one second semiconductor chip 120 in the vertical direction D3. According to some embodiments, the contact surfaces of the bonding pads that are in direct contact with each other may be viewed as one bonding pad without a boundary line.

The second lower insulating layer 126 of the lowermost second semiconductor chip 120L and the first upper insulating layer 115 of the first semiconductor chip 110 may be in direct contact. The second upper insulating layer 125 of the one second semiconductor chip 120 may be in direct contact with the second lower insulating layer 126 of the other second semiconductor chip 120 disposed on the one second semiconductor chips 120. According to some embodiments, no boundary line may be observed on the contact surface between the upper insulating layer and the lower insulating layer that are in direct contact with each other.

A third semiconductor chip 140 may be disposed on the uppermost second semiconductor chip 120U. The third semiconductor chip 140 may be a dummy chip. In exemplary embodiments, the third semiconductor chip 140 may have a thickness 140H of about 100 μm or more in the vertical direction D3. In exemplary embodiments, the thickness 140H of the third semiconductor chip 140 may be greater than the thickness in the vertical direction D3 of the first semiconductor chip 110 and the thickness 120H in the vertical direction of each of the plurality of second semiconductor chips 120. The second semiconductor chips 120 may have substantially the same thickness 120H. The thickness 120H of the second semiconductor chips 120 may be, for example, greater than or equal to 20 μm and less than or equal to 60 μm.

In exemplary embodiments, the horizontal area of the third semiconductor chip 140 may be substantially the same as the horizontal area of each of the second semiconductor chips 120. In exemplary embodiments, the horizontal area of the third semiconductor chip 140 may be less than the horizontal area of first semiconductor chip 110. The third semiconductor chip 140 may have a first width W1 in the horizontal directions D1 and D2. The first semiconductor chip 110 may have a second width W2 in the horizontal directions D1 and D2, and the second semiconductor chip 120 may have a third width W3 in the horizontal directions D1 and D2. The first width W1 may be less than the second width W2 and substantially equal to the third width W3.

The third semiconductor chip 140 may comprise a third semiconductor substrate 141. The third semiconductor substrate 141 may be formed of only a semiconductor material such as silicon or the like. According to some embodiments, a native oxide layer may be disposed on a surface of the third semiconductor substrate 141. The native oxide layer may be, for example, a silicon oxide layer. The third semiconductor chip 140 may not comprise individual devices, wiring layers, through vias, and bonding pads.

An adhesive layer 130 may be interposed between the third semiconductor chip 140 and the uppermost second semiconductor chip 120U. The horizontal area of the adhesive layer 130 may be greater than the horizontal area of the second semiconductor chip 120 and the third semiconductor chip 140. The adhesive layer 130 may comprise a polymer matrix 131 and a metal filler 133 in the polymer matrix 131. The polymer matrix 131 may be a three-dimensional network structure composed of polymers. The polymer matrix 131 may have a structure formed by three-dimensionally connecting thermosetting polymers. The metal filler 133 may have, for example, a sphere or a shape similar to a sphere. The diameter of the metal filler 133 may be, for example, 0.1 μm to 2 μm. The shape of the metal filler 133 may have other shapes in addition to a sphere. The adhesive layer 130 may comprise the metal filler 133 at a volume ratio of 60 vol % to 90 vol %. The metal filler 133 may comprise at least one metal of gold (Au), copper (Cu), nickel (Ni), aluminum (Al), and silver (Ag) or an oxide thereof. The metal filler 133 may serve as a heat dissipation path in the vertical direction D3. For example, the metal filler 133 may serve as a path for releasing heat generated during the operation of the second semiconductor chips 120.

The adhesive layer 130 may fill a space between the uppermost second semiconductor chip 120U and the third semiconductor chip 140. For example, a separation distance between the uppermost second semiconductor chip 120U and the third semiconductor chip 140 may be 3 μm to 15 μm. The separation distance may correspond to the thickness 130H of the adhesive layer 130. The thickness 130H of the adhesive layer 130 may be less than the thickness 120H of the second semiconductor chip 120. As shown in FIG. 1, the adhesive layer 130 may surround the third semiconductor chip 140 in the shape of a rectangular ring in a plan view. The adhesive layer 130 may have a fourth width in the horizontal directions D1 and D2, and the fourth width W4 may be greater than the first width W1 and the third width W3 and less than the second width W2.

As shown in FIG. 3, the uppermost second semiconductor chip 120U may comprise a bending region BA on the upper surface. Due to the bending region BA, the upper surface of the uppermost second semiconductor chip 120U may have a bent surface rather than a flat surface. The vertical length of the bending region may be about 0.45 μm. The adhesive layer 130 may fill the bending region BA.

The mold layer 150 is disposed on the first semiconductor chip 110 and may cover side surfaces of the second semiconductor chip 120 and side surfaces of the third semiconductor chip 140. The upper surface of the mold layer 150 may be located at the same plane in the horizontal directions D1 and D2 as the upper surface 140t of the third semiconductor chip 140. The mold layer 150 may be formed of, for example, an epoxy molding compound (EMC).

Referring to FIG. 4, as the number of second semiconductor chips 120 stacked on the upper surface of the first semiconductor chip 110 by direct contact of bonding pads increases, the difference in height of the contact surfaces may increase. For example, an upper surface of the uppermost second semiconductor chip 120U may be more curved than an upper surface of a lowermost second semiconductor chip 102L. As will be described later, since the topology of the contact surface is transferred and enlarged when the second semiconductor chips 120 having a small thickness are hybrid-bonded, the bending of the contact surface may increase as the number of stacked second semiconductor chips 120 increases. Hybrid bonding refers to bonding in which metal-metal direct bonding and dielectric-dielectric direct bonding are performed simultaneously. Hybrid bonding may be referred to as Hybrid Copper-to-Copper Bonding (HCB). Specifically, hybrid bonding means that after plasma treatment is performed on a contact surface of semiconductor chips at room temperature, metal bonding pad-metal bonding pad and silicon oxide-silicon oxide are in direct contact with each other at room temperature without a connection terminal such as a bump. Hybrid bonding may further comprise an annealing at a high temperature after direct contact at room temperature. The topology represents the connection (ex: shape, structure, etc.) of the surface, through which the height and the like of the surface may be known. The third semiconductor chip may have a thickness of 100 μm or more. In this thickness range, the heat dissipation effect may be effectively achieved. When hybrid bonding of the third semiconductor chip 140 and the uppermost second semiconductor chip 120U is performed in the thickness range, the third semiconductor chip 140 may not be completely in contact with the curved upper surface of the uppermost second semiconductor chip 120U, and a gap may be generated. That is, the bending region BA of the uppermost second semiconductor chip 120U remains not in contact with the third semiconductor chip 140 at the time of hybrid bonding, and a void may be generated.

According to one concept of the present invention, when the uppermost second semiconductor chip 120U and the third semiconductor chip 140 are bonded, the adhesive layer 130 may be used instead of hybrid bonding in which dielectrics are bonded to each other. As a result, a gap between the uppermost second semiconductor chip 120U and the third semiconductor chip 140 may not be generated or may be reduced. In addition, even when the third semiconductor chip 140 having a larger thickness is used, the third semiconductor chip may be easily coupled to the uppermost second semiconductor chip 120U. The adhesive layer 130 comprises a metal filler, so that heat generated from the second semiconductor chips 120 may be effectively transferred to the third semiconductor chip 140.

According to another concept of the present invention, the lowermost second semiconductor chip 120L and the first semiconductor chip 110 and the second semiconductor chips 120 may be coupled by hybrid bonding. When hybrid bonding is used, the I/O density is higher than that of the bonding method using micro bumps, so that the data bandwidth is increased, and the electrical resistance is reduced through pad-pad direct bonding, so that power consumption may be reduced. In addition, the signal transmission path is shortened, so that signal integrity is improved, and the possibility of cracking due to a difference in thermal expansion is low, so that reliability may be increased. The manufacturing process may be simplified over an underfill process or a non-conductive film (NCF) adhesion process that fills between core dies.

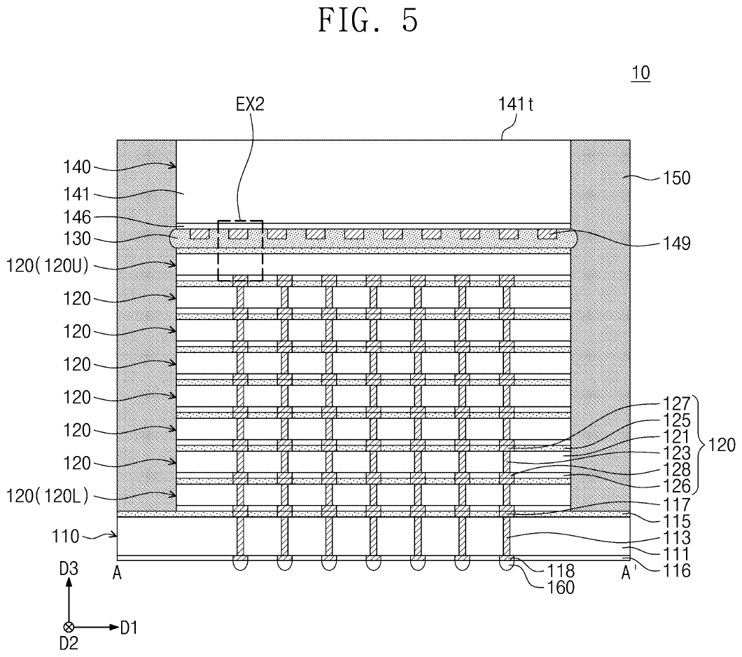

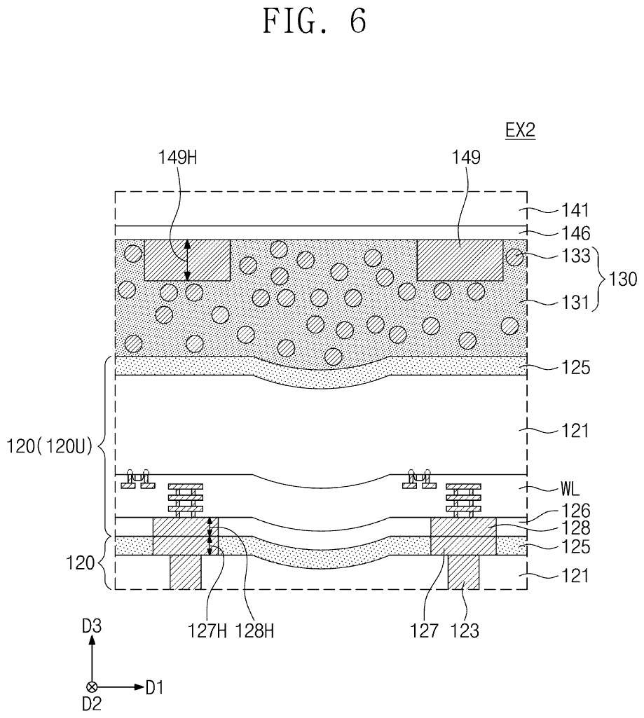

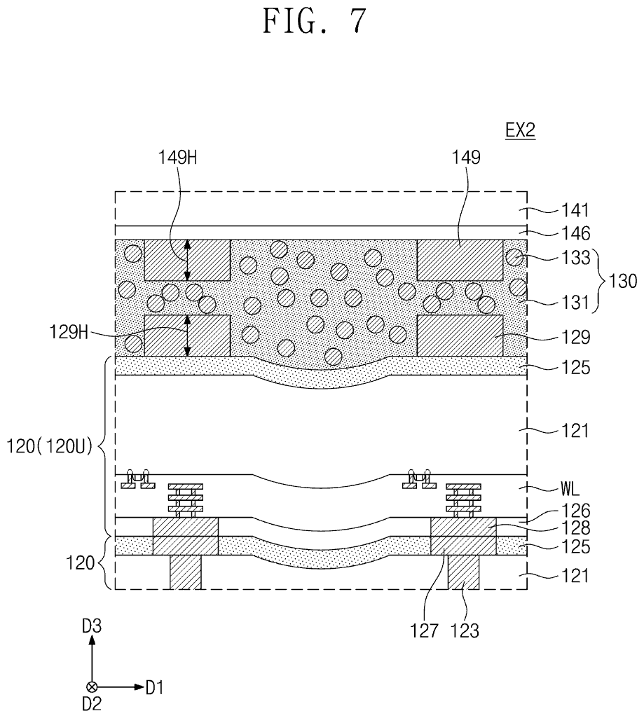

FIG. 5 is a cross-sectional view of a semiconductor package according to some embodiments. FIG. 6 is an enlarged view of ‘EX2’ of FIG. 5. FIG. 7 is an enlarged view corresponding to ‘EX2’ in FIG. 5. For concise description, an element previously described with reference to FIGS. 1, 2, and 3 may be identified by the same reference number without repeating an overlapping description thereof.

Referring to FIGS. 5 and 6, the third semiconductor chip 140 may comprise a third lower insulating layer 146 and metal patterns 149. The third lower insulating layer 146 may be disposed on a lower surface of the third semiconductor substrate 141. The third lower insulating layer 146 may comprise silicon oxide, silicon nitride, or silicon oxynitride. The metal patterns 149 may be disposed below the third lower insulating layer 146. The metal patterns 149 may extend in the vertical direction D3 from the lower surface of the third lower insulating layer 146 toward the uppermost second semiconductor chip 120U. The metal patterns 149 may overlap the second semiconductor chips 120 in the vertical direction D3. The metal patterns 149 may each be surrounded by an adhesive layer 130. For example, the side surfaces and the lower surface of each of the metal patterns 149 may be surrounded by the adhesive layer 130. The metal patterns 149 may be spaced apart from the uppermost second semiconductor chip 120U with the adhesive layer 130 therebetween in the vertical direction D3. The metal patterns 149 may serve as a heat dissipation path in the vertical direction D3. The metal filler 133 may serve as a heat dissipation path to the first metal pattern 149.

According to an aspect of the inventive concept, the metal patterns 149 may be spaced apart in the vertical direction D3 from the uppermost second semiconductor chip 120U. The upper surface of the uppermost second semiconductor chip 120U has the bending region BA. Some of the metal patterns 149 may be in contact with the upper surface of the uppermost second semiconductor chip 120U, but others may not be in contact with the upper surface of the uppermost second semiconductor chip 120U. In this case, heat may be intensively transferred to some of the metal patterns 149 that are in contact with the upper surface of the uppermost second semiconductor chip 120U, thereby reducing a heat dissipation effect through the third semiconductor chip 140. In the present invention, a metal filler 133 is disposed in a region between the metal patterns 149 and the uppermost second semiconductor chip 120U, so that heat generated from the second semiconductor chips 120 may be uniformly transferred to the third semiconductor chip 140.

The thickness 149H of each of the metal patterns 149 may be greater than the thickness 127H of the second upper bonding pad 127, and the thickness 128H of the second lower bonding pad 128, respectively. According to some embodiments, the thickness 149H of the metal pattern 149 may be greater than the sum of the thickness 127H of the second upper bonding pad 127, and the thickness 128H of the second lower bonding pad 128. The thickness 149H of the metal pattern 149 is larger than the thickness 127H of the second upper bonding pad 127 and the thickness 128H of the second lower bonding pad 128, so that the heat dissipation effect may be improved. The thickness 149H of the metal pattern 149 may be greater than a thickness of the third lower insulating layer 146. In exemplary embodiments, the thickness 149H of each of the metal patterns 149 may be greater than or equal to about 3 μm and less than or equal to approximately 4 μm. The metal patterns 149 may have a rectangular shape in cross-section parallel with the vertical direction D3. According to some embodiments, the cross-section of the metal patterns 149 may have a shape such as an inverted dome shape. In exemplary embodiments, the metal patterns 149 may be arranged in rows and columns so as to be spaced apart from each other at regular intervals in the horizontal directions D1 and D2. In exemplary embodiments, the plurality of metal patterns 149 may comprise nickel (Ni), copper (Cu), or a combination thereof. For example, the plurality of metal patterns 149 may each be formed of copper.

Referring to FIGS. 5 and 7, the uppermost second semiconductor chip 120U may further comprise a second metal pattern 129 disposed on the upper surface thereof. In the following, the metal pattern 149 of the third semiconductor chip 140 may be referred to as a first metal pattern 149.

The plurality of second metal patterns 129 may be disposed on an upper surface of the second upper insulating layer 125. The plurality of second metal patterns 129 may each extend in the vertical direction D3 from the upper surface of the second upper insulating layer 125 toward the third semiconductor chip 140. The second metal patterns 129 may each be surrounded by an adhesive layer 130. Each of the first metal patterns 149 and each of the plurality of second metal patterns 129 may overlap in the vertical direction D3. In an exemplary embodiment, the thickness 149H of the first metal pattern 149 and the thickness 129H of the second metal pattern 129 may be substantially the same or different. The first metal patterns 149 and the second metal patterns 129 may be spaced apart from each other. The separation distance in the vertical direction D3 between the first metal pattern 149 and the second metal pattern 129 may be less than each of the thickness 149H of the first metal pattern 149 and the thickness 129H of the second metal pattern 129. The spacing in the vertical direction D3 between the first metal pattern 149 and the second metal pattern 129 may be greater than the diameter of the metal filler 133. The metal filler 133 may serve as a heat dissipation path between and connecting the first metal pattern 149 and the second metal pattern 129.

In exemplary embodiments, the second metal pattern 129 may have a rectangular shape in cross-section parallel with the vertical direction D3. The second metal pattern 129 may be formed of nickel, copper, or a combination thereof, for example, the first metal pattern 149 and the second metal pattern 129 may each be formed of copper.

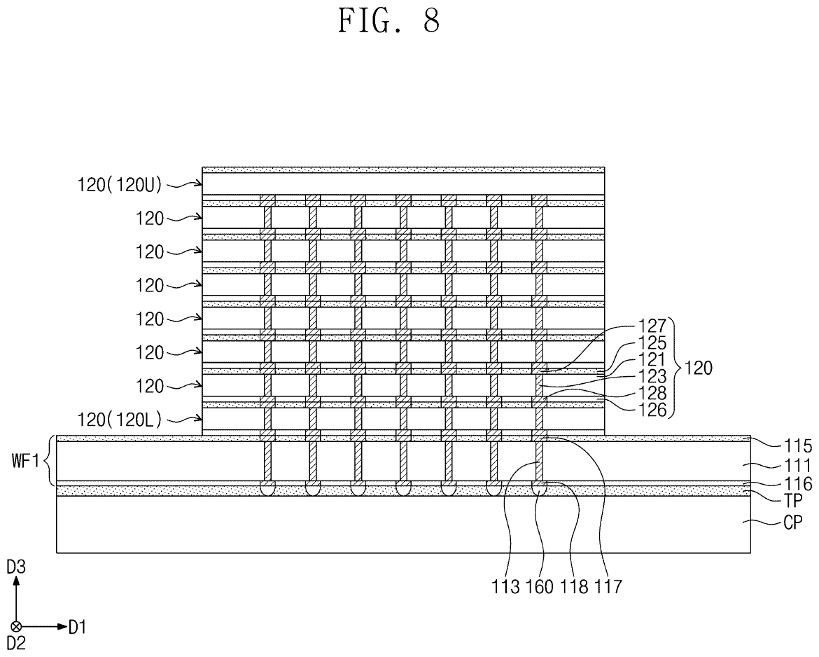

FIGS. 8, 9, 10, 11, and 12 are cross-sectional views illustrating a method of manufacturing a semiconductor package in accordance with some embodiments of the invention.

Referring to FIG. 8, a carrier substrate CP may be provided. A first wafer WF1 may be disposed on the carrier substrate CP. The first wafer WF1 may be formed of a plurality of first semiconductor chips 110 through a sawing process to be described later. That is, the first wafer WF1 may comprise a plurality of chip regions in which the first semiconductor chips 110 are to be formed. The first wafer WF1 is adhered to the carrier substrate CP by the adhesive tape TP, and the connection terminals 160 may be protected from processes to be carried out later. The second semiconductor chips 120 may be stacked on the first wafer WF1 in the vertical direction D3. The lowermost second semiconductor chip 120L and the first wafer WF1, and the second semiconductor chips 120 adjacent in the vertical direction D3 may be bonded to each other by hybrid bonding.

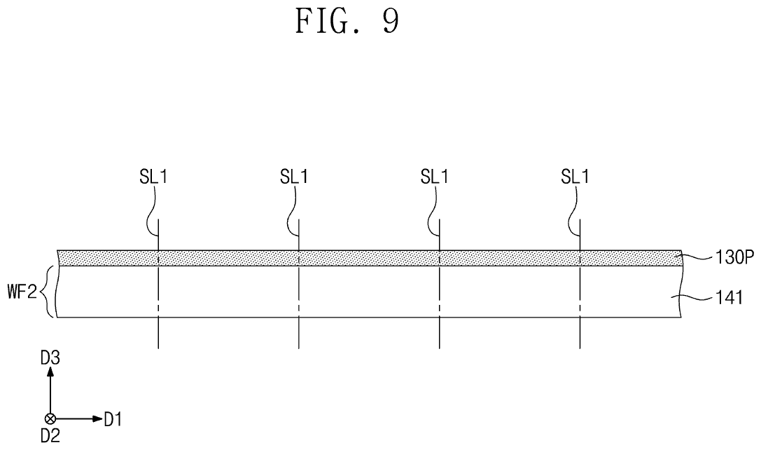

Referring to FIG. 9, a second wafer WF2 may be prepared. The second wafer WF2 may comprise a third semiconductor substrate 141. According to some embodiments, the second wafer WF2 may further comprise an insulating layer 146 on the third semiconductor substrate 141, and a metal pattern 149 (see FIG. 5). The insulating layer 146 and the metal pattern 149 may be sequentially formed on the third semiconductor substrate 141 using a known vapor deposition technique or the like. An adhesive film 130P may be attached onto the second wafer WF2. The adhesive film 130P may be, for example, an anisotropic conductive film (ACF). The adhesive film 130P may comprise a thermosetting resin, a metal filler, a curing agent, and an additive. The thermosetting resin may comprise at least one of an epoxy resin, an acrylic resin, a polyimide resin, and a polyurethane resin. The metal filler 133 may comprise at least one metal of gold (Au), copper (Cu), nickel (Ni), aluminum (Al), and silver (Ag) or an oxide thereof. The metal filler may, for example, have a spherical or sphere-like shape. The diameter of the metal filler may for example be between 0.1 μm and 2 μm. The shape of the metal filler may have various shapes in addition to a sphere. The adhesive film 130P may comprise the metal filler in a volume ratio of 60 vol % to 90 vol %. The curing agent may comprise an amine-based or imidazole-based compound. The additive may comprise a modifier for increasing the curing density, a plastic polymer material for stress relaxation, and the like. The second wafer WF2 onto which the adhesive film 130P is attached may be cut along the first sawing line SL1.

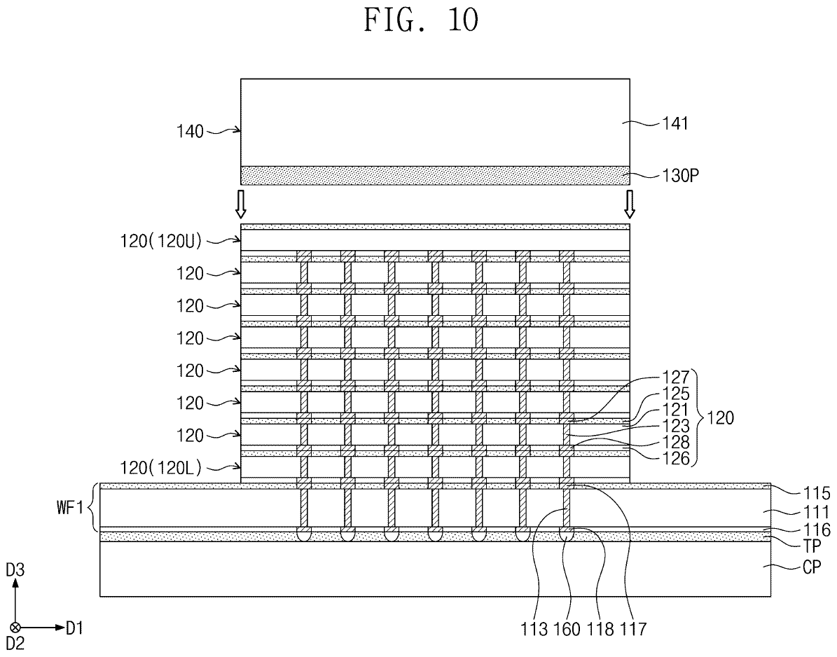

Referring to FIGS. 9 and 10, a plurality of cut adhesive films 130P and a plurality of third semiconductor chips 140 may be formed. The third semiconductor chip 140 may be disposed on the uppermost second semiconductor chip 120U. The adhesive film 130P may cover the upper surface of the uppermost second semiconductor chip 120U. The adhesive film 130P has fluidity in the thermocompression bonding process, and may fill the bending region of the upper surface of the second semiconductor chip 120U.

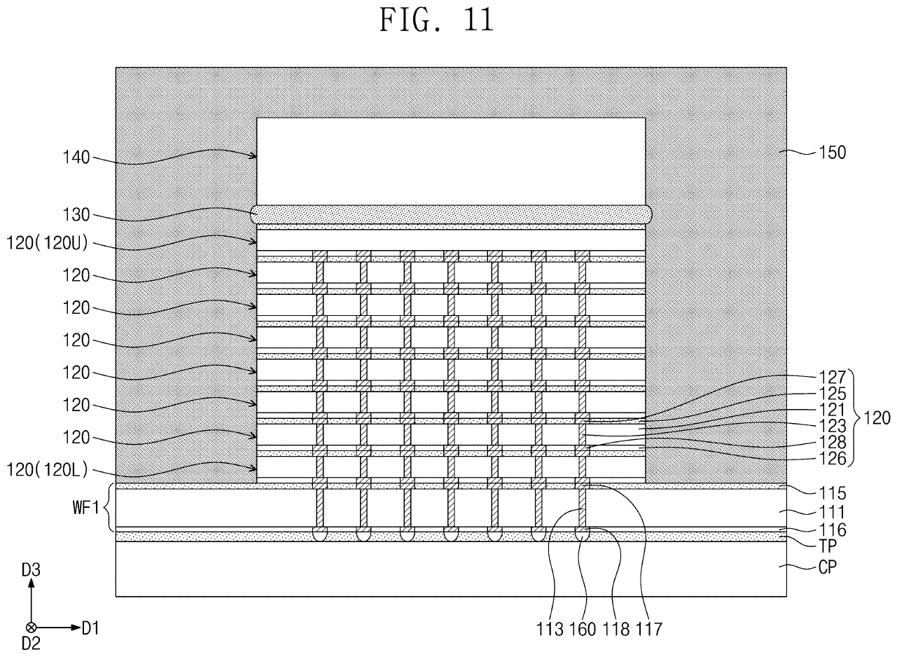

Referring to FIG. 11, the adhesive film 130P is cured through a thermocompression bonding process, so that the adhesive layer 130 may be formed. The adhesive layer 130 may protrude in the horizontal directions D1, and D2 from the side surfaces of the third semiconductor chip 140 and the side surface of the uppermost second semiconductor chip 120U in the thermocompression bonding process.

Then, a mold layer 150 covering the upper surface of the first wafer WF1, the side surfaces of the second semiconductor chips 120, the upper surface and the side surface of the third semiconductor chip 140 may be formed. The mold layer 150 may be formed by heating and curing an epoxy molding compound (EMC).

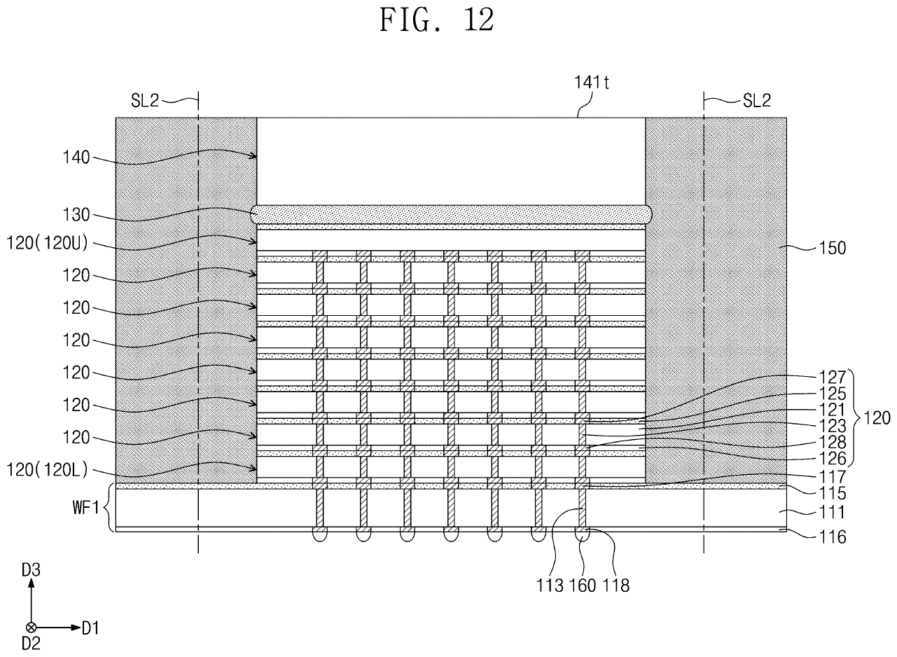

Referring to FIG. 12, the grinding process of the upper surface of the mold layer 150 may proceed such that the upper surface 140t of the third semiconductor chip 140 is exposed. The upper surface 140t of the third semiconductor chip 140 and the upper surface of the mold layer 150 may be substantially coplanar. The carrier substrate CP and the adhesive tape TP may be removed from the first wafer WF1. Along the second sawing line SL2, the mold layer 150 and the first wafer WF1 may be cut. The first wafer WF1 may be cut to form a first semiconductor chip 110 as shown in FIG. 2. As a result of the sawing process, the semiconductor package 10 of FIG. 2 may be formed.

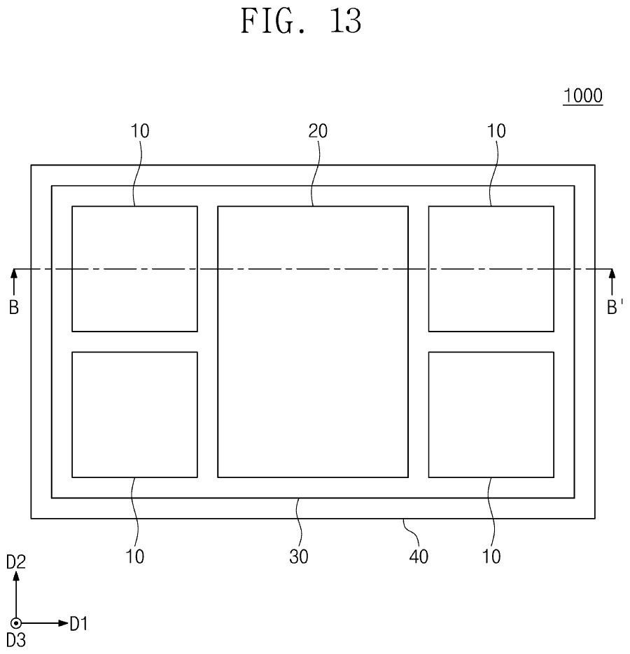

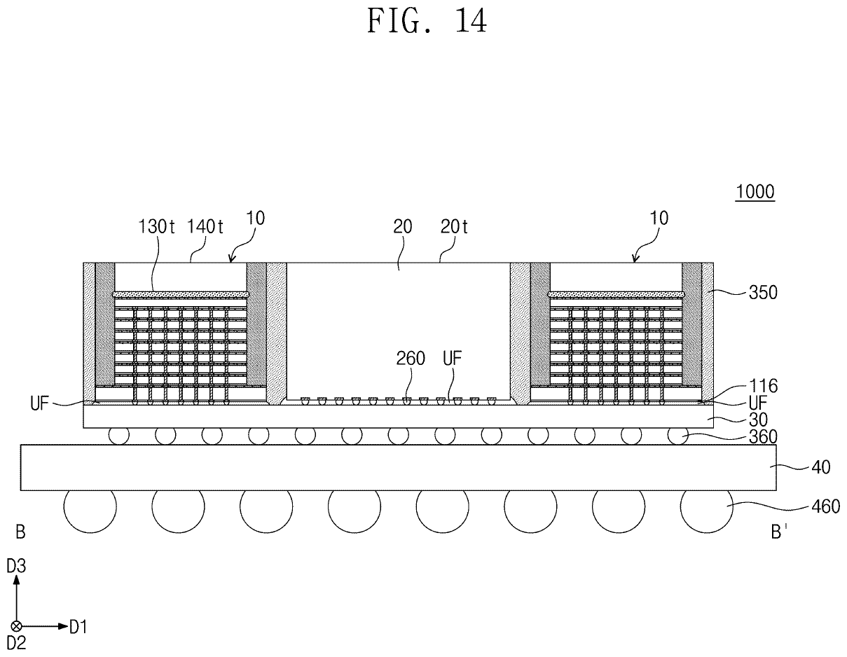

FIG. 13 is a top view of a semiconductor package according to some embodiments. FIG. 14 is a schematic cross-sectional view taken along line B-B′ in FIG. 13. For concise description, an element previously described may be identified by the same reference number without repeating an overlapping description thereof.

The semiconductor package 1000 according to some embodiments may comprise a package substrate 40, an interposer substrate 30, a fourth semiconductor chip 20, a plurality of chip stack structures 10, and an underfill layer UF. The chip stack structure 10 of FIG. 14 may correspond to the semiconductor packages 10 according to the embodiments described above with reference to FIGS. 2 and 5.

The package substrate 40 may be, for example, a printed circuit board (PCB). The package substrate 40 may be a multi-layer printed circuit board.

The package substrate 40 may comprise a substrate base (not shown), metal wirings (not shown) in the substrate base, a top pad (not shown) and a bottom pad (not shown), which are respectively formed on an upper surface and a lower surface of the substrate base. The substrate base may comprise a single base layer or a stacked structure comprising a plurality of base layers. The substrate base may be formed of at least one material selected from, for example, a phenolic resin, an epoxy resin, and polyimide. The substrate base may comprise, for example, at least one material selected from among Frame Retardant 4 (FR4), Tetrafunctional epoxy, Polyphenylene ether, Epoxy/polyphenylene oxide, Bismaleimide triazine (BT), Thermount, Cyanate ester, Polyimide and Liquid crystal polymer. Metal wirings (not shown) may connect the top pads and the bottom pads. The top pads and the bottom pads may be exposed by a solder resist layer covering the upper and lower surfaces of the substrate base, respectively. An external connection terminal 460 may be disposed on the bottom pad of the package substrate 40. The external connection terminal 460 may be, for example, a solder ball or a bump. The external connection terminal 460 may electrically connect between the semiconductor package 1000 and an external device.

The interposer substrate 30 may be disposed on a package substrate 40. The interposer substrate 30 may comprise a substrate base (not shown) made of a semiconductor material, and a top pad (not shown) and a bottom pad (not shown), respectively, formed on an upper surface and a lower surface of the substrate base. The substrate base may be, for example, a silicon substrate or a glass substrate. Internal wiring may be formed on the upper surface, the lower surface, and/or the inside of the substrate base. In addition, through vias electrically connecting the top pad and the bottom pad may be formed inside the substrate base. The interposer substrate 30 may be mounted on the package substrate 40 by internal connection terminals 360. The internal connection terminal 360 may be, for example, a solder ball or a bump.

The fourth semiconductor chip 20 and the plurality of chip stack structures 10 may be disposed on an interposer substrate 30. In one example, the fourth semiconductor chip 20 may be located in a central portion of the interposer substrate 30. With the fourth semiconductor chip 20 therebetween, the chip stack structures 10 may be spaced apart along the first direction D1. As shown in FIG. 13, two chip stack structures 10 may be disposed adjacent to one side of the chip of the fourth semiconductor chip 20, and two chip stack structures may also be disposed adjacent to the other side. The adjacently disposed chip stack structures 10 may be spaced apart from each other along the second direction D2. According to some embodiments, three of the chip stack structures 10 may be disposed adjacent to one side of the fourth semiconductor chip 20 and three may be disposed adjacent the other side. A plurality of chip stack structures 10 are provided, and the arrangement may vary.

The fourth semiconductor chip 20 may be spaced apart from the chip stack structures 10 in the first direction D1. The fourth semiconductor chip 20 may be a semiconductor chip having a function different from those of the first semiconductor chip 110 and the second semiconductor chip 120. The fourth semiconductor chip 20 may transmit a signal to or receive a signal from the chip stack structure 10. The fourth semiconductor chip 20 may be a logic chip. The fourth semiconductor chip 20 may be a processor unit. For example, the fourth semiconductor chip 20 may be an ASIC (Application-Specific Integrated Circuit), an MPU (micro-processor unit), a CPU (Central Processing Unit), or a GPU (graphic processor unit). The fourth semiconductor chip 20 may be electrically connected to the interposer substrate 30 through a first connection terminal 260 arranged on the active surface. The first connection terminal 260 may be, for example, a solder ball or a bump. The level of the upper surface 20t of the fourth semiconductor chip 20 may be substantially the same as the level of the upper surfaces 140t of the chip stack structure 10. The level of the upper surface 130t of the adhesive layer 130 of the chip stack structure 10 may be lower than the level of the upper surfaces 20t of the fourth semiconductor chips 20.

The level of the upper surface of the fourth semiconductor chip 20 may be located at substantially the same level as the level of the upper surfaces of the chip stack structure 10. The thickness of the fourth semiconductor chip 20 may be adjusted in the process of being formed from a wafer, and the third semiconductor chip 140 and the adhesive layer 130 serving as heat dissipation like the chip stack structure 10 may not be required.

An underfill layer UF may be interposed between the chip stack structure 10 and the interposer substrate 30, and between the fourth semiconductor chip 20 and the interposer substrate 30, respectively. The underfill layer UF comprises a polymer matrix and may be formed of an epoxy material comprising an epoxy resin, a filler, and an additive. The filler may comprise, for example, silica (SiO₂).

The second mold layer 350 may be disposed on the package substrate 40. In the foregoing, the mold layer 150 of the chip stack structure 10 may be referred to as a first mold layer 150 (see FIG. 1). The second mold layer 350 may surround the sides of the chip stack structure 10 and the sides of the fourth semiconductor chip 20. The second mold layer 350 may fill the space between the chip stack structures 10 and between the chip stack structure 10 and the fourth semiconductor chip 20. The second mold layer 350 may be formed of, for example, an epoxy molding compound (EMC). The second mold layer 350 may be formed separately from the first mold layer 150 of the chip stack structure 10. The second mold layer 350 may not cover the upper surface of the chip stack structure 10 and the upper surface of a fourth semiconductor chip 20.

According to one concept of the invention, each of the chip stack structures 10 may individually comprise a third semiconductor chip 140 and an adhesive layer 130. That is, even when a plurality of chip stack structures 10 are present, each chip stack structure 10 may comprise an independent third semiconductor chip 140 and adhesive layer 130, and may not share them with other chip stack structures 10. According to the comparative example, when the horizontal area of the third semiconductor chip 140 is more than twice as large as that of the second semiconductor chip 120, one third semiconductor chip 140 may be disposed over the uppermost second semiconductor chip 120U of the two second semiconductor chips 120 at positions separated in the horizontal direction ex (ex: D2). In such an arrangement, a height difference is likely to occur when the third semiconductor chips 140 are bonded, and as a result, there is a risk that mechanical stresses are unbalanced and package reliability is degraded. In addition, if the third semiconductor chip 140 is not uniformly attached over the uppermost second semiconductor chip 120U spaced apart in the horizontal direction, a gap may be formed in the adhesive layer 130. When such voids are generated, the adhesive strength decreases, and there is a possibility that a long-term reliability problem occurs. On the other hand, since the thickness of the fourth semiconductor chip 20 is relatively easy to adjust, a desired heat dissipation effect may be achieved through the thickness adjustment. Additional third semiconductor chip 140 and adhesive layer 130 may not be required on the fourth semiconductor chip 20.

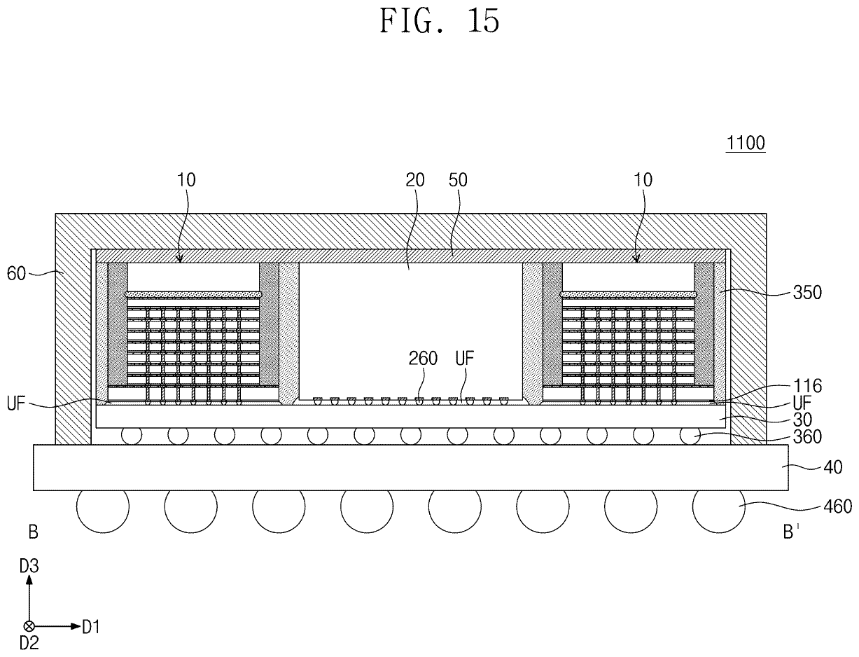

According to some embodiments, as shown in FIG. 15, the semiconductor package 1100 may further comprise a thermally conductive material layer 50 and a heat sink 60. The thermally conductive material layer 50 may be disposed on and cover the upper surface of the chip stack structure 10, the upper surface of second mold layer 350, and the upper surface of fourth semiconductor chip 20. The thermally conductive material layer 50 may comprise a thermal interface material (TIM). The thermal interface material may comprise, for example, a thermally conductive grease and a highly thermally conductive material such as a metal thin film. The heat sink 60 may be disposed on the package substrate 40. In exemplary embodiments, the heat sink 60 may comprise a horizontal portion and a vertical portion that are connected to each other. The horizontal portion may be disposed on an upper surface of the thermally conductive material layer 50. The vertical portion may surround a side of the second mold layer 350 and a side of the interposer substrate 30. Although the upper surface of the horizontal portion of the heat sink 60 is illustrated as being flat surface, according to some embodiments, the upper surface of a horizontal portion may have a structure in which a plurality of fins are disposed. The heat sink 60 may comprise a metal such as aluminum and copper.

According to an aspect of the inventive concept, a thick dummy chip may be disposed on the uppermost semiconductor chip of the semiconductor chips forming the hybrid bonding. An adhesive layer may be interposed between the dummy chip and the uppermost semiconductor chip, and the adhesive layer may comprise a polymer and a metal filler. By using the adhesive layer, a gap between the dummy chip and the uppermost semiconductor chip may be reduced, and heat dissipation characteristics may be improved. For these reasons, the reliability of the semiconductor package may be increased.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a first semiconductor chip;
second semiconductor chips stacked on the first semiconductor chip;
a third semiconductor chip on the second semiconductor chips; and
an adhesive layer between the third semiconductor chip and an uppermost second semiconductor chip of the second semiconductor chips,
wherein the second semiconductor chips are connected to each other via direct contact of bonding pads, and
wherein the adhesive layer comprises a polymer and a metal filler.

2. The semiconductor package of claim 1, wherein the third semiconductor chip has a first width in a horizontal direction, and the first semiconductor chip has a second width in the horizontal direction, and
wherein the first width is smaller than the second width.

3. The semiconductor package of claim 1, wherein the third semiconductor chip has a first width in a horizontal direction, and each of the second semiconductor chips has a third width in the horizontal direction, and
wherein the first width and the third width are the same.

4. The semiconductor package of claim 1, wherein a separation distance in a vertical direction between the uppermost second semiconductor chip and the third semiconductor chip is 3 μm to 15 μm.

5. The semiconductor package of claim 1, wherein the adhesive layer comprises the metal filler in a volume ratio of 60 vol % to 90 vol %.

6. The semiconductor package of claim 1, wherein a thickness of the third semiconductor chip is at least twice a thickness of each of the second semiconductor chips.

7. The semiconductor package of claim 1, wherein the third semiconductor chip has a thickness of 100 μm or more.

8. The semiconductor package of claim 1, wherein a thickness of each of the second semiconductor chips is greater than or equal to 20 μm and less than or equal to 60 μm.

9. The semiconductor package of claim 1, wherein the metal filler comprises at least one metal of gold (Au), copper (Cu), nickel (Ni), aluminum (Al), and silver (Ag) or an oxide thereof.

10. The semiconductor package of claim 1, wherein the third semiconductor chip is a dummy chip.

11. The semiconductor package of claim 1, wherein the third semiconductor chip comprises one or more first metal patterns disposed on a lower surface thereof, and
wherein the one or more first metal patterns are spaced apart from the uppermost second semiconductor chip in a vertical direction.

12. The semiconductor package of claim 11, wherein a thickness of a first metal pattern in the one or more first metal patterns is greater than a sum of thicknesses of the bonding pads.

13. The semiconductor package of claim 11, wherein the uppermost second semiconductor chip further comprises one or more second metal patterns disposed on an upper surface, and
wherein the one or more second metal patterns are vertically aligned and spaced apart from the one or more first metal patterns.

14. The semiconductor package of claim 13,
wherein the one or more first metal patterns comprise a plurality of first metal patterns that are spaced apart from each other in a horizontal direction, and
wherein the one or more second metal patterns comprise a plurality of second metal patterns that are spaced apart from each other in the horizontal direction.

15. The semiconductor package of claim 13, wherein a diameter of the metal filler is smaller than a separation distance between a first metal pattern in the one or more first metal patterns and a second metal pattern in the one or more second metal patterns that are adjacent to each other in a vertical direction.

16. A semiconductor package comprising:
a first semiconductor chip;
second semiconductor chips stacked on the first semiconductor chip;
a third semiconductor chip on the second semiconductor chips; and
an adhesive layer between the third semiconductor chip and an uppermost second semiconductor chip of the second semiconductor chips,
wherein each of the second semiconductor chips comprises an upper insulating layer disposed at an upper end thereof and a lower insulating layer disposed at a lower end thereof,
wherein an upper insulating layer of a lower second semiconductor chip of two vertically adjacent second semiconductor chips is in direct contact with a lower insulating layer of the upper second semiconductor chip,
wherein each of the upper insulating layer and the lower insulating layer comprises a dielectric, and
wherein the adhesive layer comprises a polymer matrix and a metal filler in the polymer matrix.

17. The semiconductor package of claim 16, wherein each of the upper insulating layer and the lower insulating layer comprises any one of silicon oxide, silicon nitride, and silicon oxynitride.

18. A semiconductor package comprising:
a package substrate;
an interposer substrate on the package substrate;
a semiconductor chip on the interposer substrate; and
one or more chip stack structures each separated from the semiconductor chip in a horizontal direction,
wherein a chip stack structure in the one or more chip stack structures comprises:
a first semiconductor chip;
second semiconductor chips stacked on the first semiconductor chip;
a third semiconductor chip on the second semiconductor chips;
an adhesive layer between the third semiconductor chip and an uppermost second semiconductor chip of the second semiconductor chips; and
a first mold layer disposed on the first semiconductor chip, the first mold layer covering side surfaces of the second semiconductor chips, a side surface of the third semiconductor chip, and a side surface of an adhesive layer,
wherein each of the first semiconductor chip and the second semiconductor chips comprises through vias,
wherein the adhesive layer comprises a polymer and a metal filler, and
wherein a level of an upper surface of the adhesive layer is lower than a level of an upper surface of the semiconductor chip.

19. The semiconductor package of claim 18, further comprising:
a second mold layer on the interposer substrate, the second mold layer covering side surfaces of the one or more chip stack structures and side surfaces of the semiconductor chip; and
a thermally conductive material layer on an upper surface of the second mold layer, an upper surface of each of the one or more chip stack structures, and an upper surface of the semiconductor chip; and
a heat sink provided on an upper surface of the thermally conductive material layer and surrounding a side surface of the second mold layer and a side surface of an interposer substrate on the package substrate.

20. The semiconductor package of claim 18, wherein the one or more chip stack structures comprise a plurality of chip stack structures,
wherein each respective stack structure in the plurality of chip stack structures comprises a corresponding third semiconductor chip and a corresponding adhesive layer that are not shared with any other stack structure in the plurality of chip stack structures.
